(19) United States
(12) Patent Application Publication
(10) Pub. No.: US 2026/0358430 A1
(43) Pub. Date: Nov. 12, 2026

(54) DEVICE AND METHOD FOR DIAGNOSING A BATTERY, AND A VEHICLE INCLUDING SAME

(71) Applicants: HYUNDAI MOTOR COMPANY, Seoul (KR); KIA CORPORATION, Seoul (KR)

(72) Inventors: Hyun Jun Jang, Hwaseong-si (KR); Min Jun Park, Hwaseong-si (KR); Jung Heon Lee, Hwaseong-si (KR)

(73) Assignees: HYUNDAI MOTOR COMPANY, Seoul (KR); KIA CORPORATION, Seoul (KR)

(21) Appl. No.: 19/354,643

(22) Filed: Oct. 9, 2025

(30) Foreign Application Priority Data
May 12, 2025 (KR) 10-2025-0061403

(51) Int. Cl. G01R 31/392; G01R 31/367; G01R 31/3842; G01R 31/389; G01R 31/396

(52) U.S. Cl. CPC G01R 31/392; G01R 31/367; G01R 31/3842; G01R 31/389; G01R 31/396

(57) ABSTRACT

A battery diagnostic device includes a controller configured to determine, for each cell of a battery, final resistance values based on a plurality of algorithms, determine a resistance value of each cell based on the final resistance values determined based on the plurality of algorithms and respective determination times at which the final resistance values are determined, and determine a state of health based on resistance (SoH_{R}) of the battery based on the resistance value of each cell. The battery diagnostic device also includes an output device configured to transmit the SoH_{R} to an external device.

### CROSS-REFERENCE TO THE RELATED APPLICATION

This application claims the benefit of and priority to Korean Patent Application No. 10-2025-0061403, filed on May 12, 2025, the entire contents of which are hereby incorporated herein by reference.

### BACKGROUND

### 1. Technical Field

The present disclosure relates to a battery diagnostic device and method for determining the state of health of a battery, and a vehicle including same.

### 2. Description of the Related Art

Due to repeated charging and discharging and aging of a battery, the internal resistance of the battery may increase. The battery state determined based on change in the internal resistance of the battery is called a state of health based on resistance (SoH_{R}) of the battery.

The matters described as the background technology above are only for the purpose of enhancing understanding of the background of the present disclosure, and do not acknowledge that the matters correspond to prior art already known to a person or ordinary skill in the art.

### SUMMARY

Embodiments of the present disclosure provide a battery diagnostic device and method capable of determining the state of health based on resistance (SoH_{R}) of a battery, and a vehicle including the device.

Embodiments of the present disclosure provide a battery diagnostic device and method capable of determining the SoH_{R} of a battery under various conditions based on a plurality of different algorithms, and a vehicle including the device.

Embodiments of the present disclosure provide a battery diagnostic device and method capable of determining the SoH_{R} of a battery regardless of the type of battery or vehicle, and a vehicle including the device.

Embodiments of the present disclosure provide a battery diagnostic device and method capable of improving the accuracy of a determined SoH_{R} of a battery, and a vehicle including the device.

In some aspects, determination of SoH_{R} according to embodiments of the present disclosure may be used to meet regulations requiring quantitative evaluation of the state of health of next-generation electric vehicle batteries (e.g., EURO7 emission regulations and ACC2 (Advanced Cell Chemistry 2), etc.

The aspects to be achieved in the present disclosure are not limited to the aspects mentioned above. Other aspects not mentioned herein should be more clearly understood by a person having ordinary skill in the art to which the present disclosure pertains from the description below.

In accordance with an aspect of the present disclosure, a device for diagnosing a battery is provided. The device includes a controller configured to determine, for each of cell of a battery, final resistance values based on a plurality of algorithms. The controller is also configured to determine a resistance value of each cell of the battery based on i) the final resistance values determined based on the plurality of algorithms and ii) respective determination times at which the final resistance values are determined. The controller is additionally configured to determine a state of health based on resistance (SoH_{R}) of the battery based on the resistance value of each cell. The device also includes an output device configured to transmit the SoH_{R} to an external device.

According to an embodiment, the controller may be configured to determine weights corresponding to the final resistance values for the plurality of algorithms based on the respective determination times, and determine the resistance value of each cell based on values obtained by applying the corresponding weights to the final resistance values.

According to an embodiment, the controller may be configured to set the weights such that a sum of the weights is at least approximately equal to 1.

According to an embodiment, the controller may be configured to determine the weights based on differences between the respective determination times at which the final resistance values are determined and a determination time at which the resistance value of each cell is determined.

According to an embodiment, the controller may be configured to determine the weights such that the weights increase as a difference between the determination time of the resistance value and the determination time of each of the final resistance values to which the weights correspond decreases.

According to an embodiment, the controller may be configured to determine a current resistance value for each of the plurality of algorithms based the corresponding algorithm, and determine a primarily filtered resistance value based on the current resistance value and a previous resistance value determined for the corresponding algorithm before the current resistance value for the corresponding algorithm is determined.

According to an embodiment, the controller may be configured to re-determine the current resistance value based on the current resistance value being greater than a value obtained by multiplying the previous resistance value by a preset upper limit multiple, or based on the current resistance value being less than a value obtained by multiplying the previous resistance value by a preset lower limit multiple.

According to an embodiment, the controller may be configured to determine the primarily filtered resistance value as a sum of a value obtained by multiplying the current resistance value by a weight corresponding to the current resistance value and a value obtained by multiplying the previous resistance value by a weight corresponding to the previous resistance value.

According to an embodiment, the controller may be configured to store the primarily filtered resistance value, determine the primarily filtered resistance value as the previous resistance value, and re-determine the current resistance value.

According to an embodiment, based on a preset number of primarily filtered resistance values being stored for a particular algorithm among the plurality of algorithms, the controller may be configured to determine the final resistance value for the particular algorithm based on the primarily filtered resistance values.

According to an embodiment, the controller may be configured to determine a final resistance value for a particular algorithm among the plurality of algorithms by further considering whether a variance of the primarily filtered resistance values for the particular algorithm is equal to or less than a preset value.

According to an embodiment, the controller may be configured to determine whether preset execution conditions are satisfied for the plurality of algorithms, and determine the final resistance values for one or more algorithms that satisfy the preset execution conditions.

According to an embodiment, the preset execution conditions may include whether a temperature of each cell of the battery satisfies preset temperature conditions.

According to an embodiment, the preset execution conditions may include whether a state of charge (SoC) of each cell of the battery satisfies preset SoC conditions.

According to an embodiment, the plurality of algorithms may include an algorithm for determining a final resistance value based on a voltage change amount for a preset first time after charging starts, an average current for the first time, a voltage change amount for a preset second time after charging ends, and an average current for the second time in a charging mode of the battery.

According to an embodiment, the plurality of algorithms may include an algorithm for determining a final resistance value based on frequency data obtained by converting current data including a current value of each cell over a preset time into a frequency domain in a mode in which charging and discharging of the battery are repeated.

According to an embodiment, the plurality of algorithms may include an algorithm for determining a final resistance value by performing least mean squares based on a current value and a voltage value of each cell for a preset period time in the mode in which charging and discharging of the battery are repeated.

According to an embodiment, the plurality of algorithms may include an algorithm for determining a final resistance value based on average values of a current change amount in each cell during a preset time and a voltage change amount in each cell during the preset time in the mode in which charging and discharging of the battery are repeated.

In accordance with another aspect of the present disclosure, a method of diagnosing a battery is provided. The method includes determining, by a controller, for each cell of a battery, final resistance values based on a plurality of algorithms. The method also includes determining, by the controller, a resistance value of each cell of the battery based on i) the final resistance values determined based on the plurality of algorithms and ii) respective determination times at which the final resistance values are determined. The method additionally includes determining, by the controller, an SoH_{R} of the battery by the controller based on the resistance value of each cell. The method further includes transmitting, by the controller, the SoH_{R} to an external device.

In accordance with a further aspect of the present disclosure, a vehicle is provided. The vehicle includes a battery including a plurality of cells. The vehicle also includes a battery diagnostic device configured to determine final resistance values based on a plurality of algorithms, determine a resistance value of each cell based on i) the final resistance values determined based on the plurality of algorithms and ii) respective determination times at which the final resistance values are determined, and determine an SoH_{R} of the battery based on the resistance value of each cell.

### BRIEF DESCRIPTION OF THE DRAWINGS

The above and other aspects, features, and other advantages of the present disclosure should be more clearly understood from the following detailed description taken in conjunction with the accompanying drawings, in which:

FIGS. 1 and 2 illustrate a battery and a battery diagnostic device according to an embodiment;

FIG. 3 illustrates a battery diagnostic method according to an embodiment;

FIG. 4 illustrates a first algorithm among a plurality of algorithms according to an embodiment;

FIG. 5 illustrates second to fourth algorithms among the plurality of algorithms according to an embodiment;

FIG. 6 illustrates a primary filtering process according to an embodiment;

FIG. 7 illustrates a secondary filtering process according to an embodiment;

FIG. 8 illustrates a process of determining a final resistance value according to an embodiment;

FIGS. 9 and 10 illustrate the first algorithm in a charging mode according to an embodiment;

FIG. 11 illustrates the second algorithm in a mode in which charging and discharging are repeated according to an embodiment; and

FIGS. 12 and 13 illustrate the secondary filtering process according to an embodiment.

### DETAILED DESCRIPTION

In the following description, where it was determined that a detailed description of known functions and configurations incorporated would obscure the gist of the present disclosure, the detailed description thereof has been omitted. In addition, the accompanying drawings are merely intended to facilitate understanding of the embodiments of the present disclosure. The technical ideas disclosed in the present disclosure are not limited by the accompanying drawings. It should be understood that the present disclosure includes all modifications, equivalents, or substitutes included in the spirit and scope of the present disclosure. The following description is not intended to limit the present disclosure to the described form or a specific field. Rather, it is contemplated that various alternative aspects and modifications to the present disclosure are possible, whether explicitly described or implied in the present disclosure. Those having ordinary skill in the art to which the present disclosure pertains should recognize that the form and details of the present disclosure may be changed.

The present disclosure is described with reference to specific aspects. However, as should be understood by those having ordinary skill in the art to which the present disclosure pertains, various embodiments of the present disclosure may be modified or implemented in various other ways without departing from the spirit and scope of the present disclosure. Accordingly, the following description should be considered illustrative and is intended to enable those having ordinary skill in the art to make and use the various embodiments. It should be understood that the forms in which the disclosure is illustrated and described herein should be taken as representative embodiments. Equivalent elements, materials, processes, or steps may be substituted for those illustrated and described herein.

The terms “including”, “comprising”, “incorporating”, “consisting of”, “have”, “is”, and the like, used in the present disclosure, should be construed in a non-exclusive manner, i.e., to allow for other items, components, or elements not explicitly listed therein to be represented. Additionally, reference to the singular should be construed to include the plural.

Furthermore, the various embodiments described herein should be taken in an illustrative and explanatory sense and should not be construed as limiting the scope of the present disclosure. Any references to joining (e.g., attached, affixed, coupled, connected, etc.) are used solely to aid understanding of the present disclosure and do not imply limitations as to the location, orientation, or use of a configuration or method disclosed herein. Accordingly, if joining references exist, they should be interpreted broadly. Moreover, such joining references do not imply that two or more elements are directly connected to one another.

Additionally, any numeric terms, such as “first”, “second”, “third”, “primary”, “secondary”, “main”, or any other general term or numeric term, should be taken only as identifiers to aid in understanding the various components, forms, variations or modifications of the present disclosure. These terms do not imply any limitation on any component, form, variation or modification or order or preference thereof. These expressions may be used to describe various components, but the components are not limited by the expressions. The expressions are used only for the purpose of distinguishing one component from another.

The suffixes “module” and “part” used for components in the following description are given or used interchangeably solely for the convenience of writing the specification, and do not have a distinct meaning or role.

When a component is referred to as being “coupled” or “connected” to another component, it should be understood that the component may be directly coupled or connected to the other component, but that there may also be one or more other components therebetween. On the other hand, when it is said that a component is “directly coupled” or “directly connected” to another component, it should be understood that there are no other components therebetween.

When a component, controller, device, element, unit, apparatus, or the like of the present disclosure is described as having a purpose or performing an operation, function, or the like, the component, controller, device, element, unit, apparatus, or the like should be considered herein as being “configured to” meet that purpose or to perform that operation or function. Each component, controller, device, element, unit, apparatus, and the like may separately embody or be included with a processor and a memory, such as a non-transitory computer readable media, as part of the apparatus.

In addition, a unit or a control unit included in a name is a term widely used in naming a controller that controls a specific function of a vehicle, and does not mean a generic functional unit.

The controller may include a communication device that communicates with other controllers or sensors to control the function thereof, a memory that stores an operating system or logic instructions and input/output information, and one or more processors that perform determination, computation, decisions, etc. necessary for controlling the functions thereof.

Any number of components or various components in any of the configurations described in the present specification may be included in the disclosure described in this specification. The components may include any combination of features described in the present disclosure and may be arranged in any of the various configurations described in the present disclosure. The concepts regarding the structure and arrangement of the components of the present disclosure as well as the use and operation of the components may be applied to any number of embodiments in any combination as well as to the specific embodiments discussed in the present disclosure. Embodiments including those having various features in various arrangements are described below with reference to the accompanying drawings.

Hereinafter, various embodiments of the present disclosure are described in detail with reference to the accompanying drawings. Regardless of the drawing numerals, identical or similar components are given the same reference numerals and redundant descriptions thereof have been omitted.

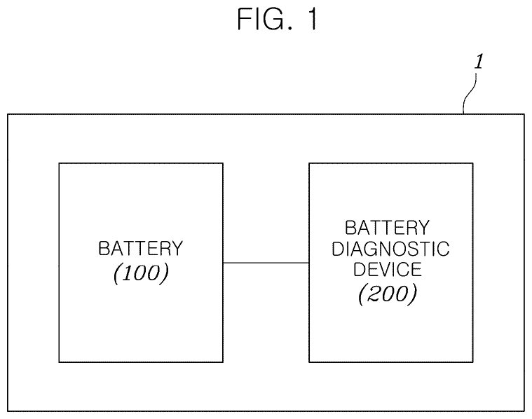

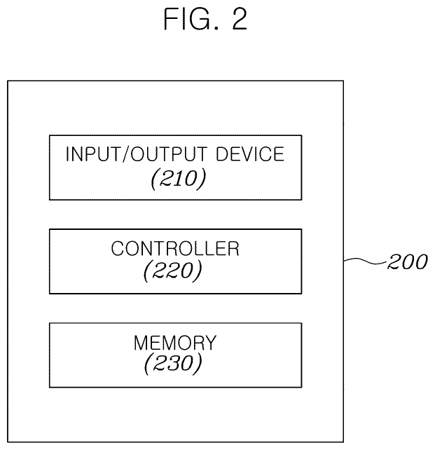

FIGS. 1 and 2 illustrate a vehicle and a battery diagnostic device according to an embodiment.

Referring to FIG. 1, a vehicle 1 includes a battery 100 and a battery diagnostic device 200. The battery diagnostic device 200 includes an input/output device 210, a controller 220, and a memory 230.

The battery 100 stores electric power and can perform charging and discharging of the stored electric power. For example, the battery 100 may be a battery pack including a plurality of battery cells.

The battery diagnostic device 200 may determine the SoH_{R} of the battery 100, or each of the plurality of cells included in the battery 100, based on the internal resistance values of the cells included in the battery 100. In the following description, determining the resistance value of the battery 100 or determining the resistance value of each cell may mean determining the internal resistance value of each of the plurality of cells constituting, or included in, the battery 100.

The input/output device 210 may transmit data obtained by the battery diagnostic device 200 or the SoH_{R} determined by the battery diagnostic device 200 to an external device.

The input/output device 210 may include an input unit that acquires current data and voltage data of the battery 100 and transmits the same to the controller 220, and an output unit that transmits the SoH_{R} determined by the controller 220 to an external device (e.g., an AVNT (Audio, Video, Navigation and Telematics) terminal (not shown) and/or other controller (not shown) of a vehicle). The external device may provide an indication of the SoH_{R} of the battery (or of each cell of the battery) to a user (e.g., a driver of the vehicle) via a visual and/or audio display. Additionally, or alternatively, the external device may control operation of the vehicle based on the SoH_{R} of the battery (or of each cell of the battery). For example, when the SoH_{R} of the battery falls below a preset threshold, the external device (e.g., a vehicle controller, powertrain control unit, or battery management system) may restrict high-load operations such as rapid acceleration, high-speed driving, or battery overcharging to prevent further degradation or safety issues. In another example, the external device may switch the vehicle into a limited operation mode or prompt a maintenance alert to notify the driver of the need for battery service. Additionally, the SoH_{R} may be utilized to adjust the vehicle's energy management strategy, such as limiting power draw or adjusting regenerative braking strength, in accordance with the health state of the battery.

The controller 220 may determine final resistance values for a plurality of different algorithms based on the algorithms, determine the resistance value of each cell based on the final resistance values for the algorithms and the time when each of the final resistance values is determined, and determine the SoH_{R} of the battery 100 based on the resistance value of each cell. In an embodiment, “a plurality of different algorithms” may be a plurality of algorithms that may independently determine the internal resistance value of each cell included in the battery 100, “final resistance values for the plurality of algorithms” may mean resistance values determined based on the plurality of different algorithms, and “resistance value of each cell” may mean the internal resistance of each cell determined based on the final resistance values for the plurality of algorithms.

The memory 230 may store information used by the controller 220 to determine the SoH_{R}. For example, the memory 230 may store the final resistance values for the plurality of algorithms determined by the controller 220 and the time when each of the final resistance values of the plurality of algorithms is determined.

Although the battery diagnostic device 200 is generally described herein as being included in the vehicle 1, the battery diagnostic device 200 does not necessarily have to be included in the vehicle 1. For example, the battery diagnostic device 200 may be similarly used for other systems or devices that require electric power storage and diagnosis.

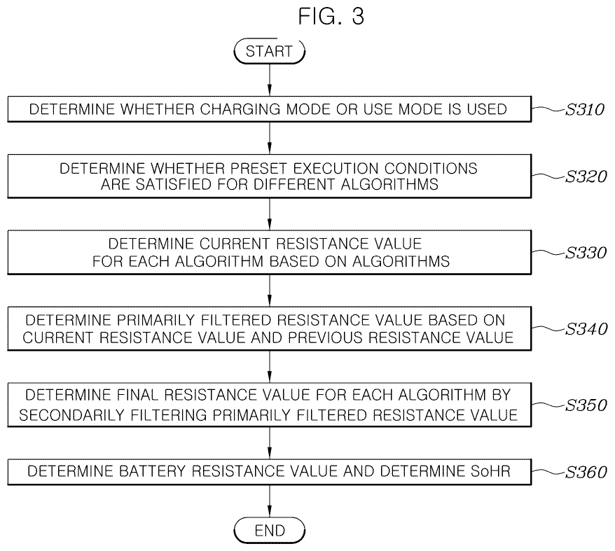

FIG. 3 illustrates a battery diagnostic method according to an embodiment.

Referring to FIG. 3, in an operation. S310, the controller 220 may determine whether the battery is in a charging mode or a use mode.

In an embodiment, the charging mode may be a state in which electric power is supplied to the battery 100 and the battery 100 is charged with the electric power. In an embodiment, the use mode may be a state in which the battery is repeatedly charged and discharged.

For example, the use mode may correspond to a driving state of the vehicle 1 in which the vehicle 1 repeatedly performs discharging during driving and charging through regenerative braking to repeatedly charge and discharge the battery 100.

However, the above-described charging mode and use mode are illustrative, and the charging mode and use mode may be set differently depending on the target to which the battery diagnostic device 200 is applied.

In an operation S320, the controller 220 may determine whether a preset execution condition is satisfied for each of a plurality of different algorithms.

For example, the preset execution condition may include at least one of whether the temperature of the battery 100 satisfies a preset temperature condition or whether the state of charge (SoC) of the battery 100 satisfies a preset SoC condition.

In an operation S330, the controller 220 may determine the current resistance value of each cell of the battery 100 corresponding to each algorithm based on each of the plurality of algorithms.

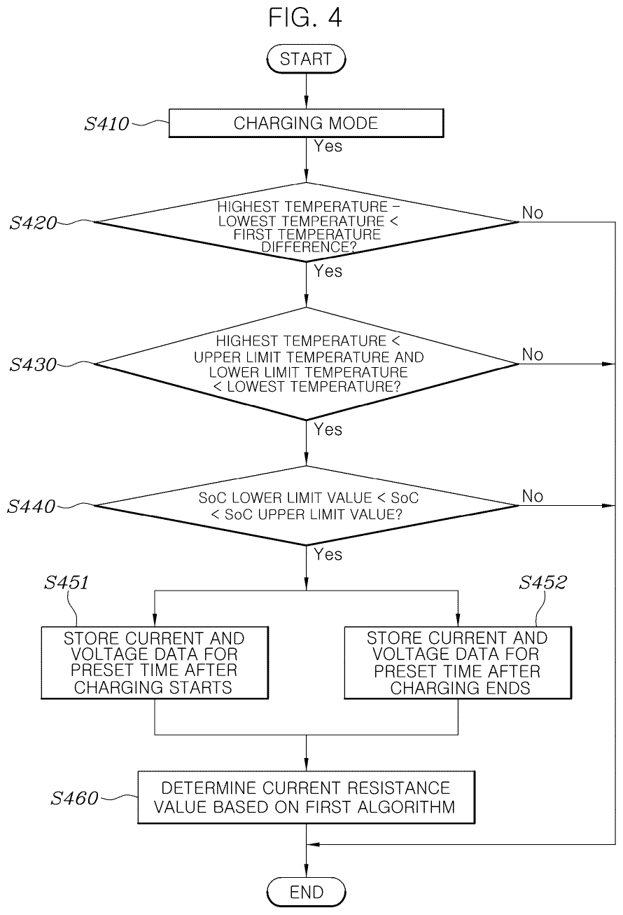

For example, the plurality of algorithms may include a first algorithm that determines the current resistance value of each cell based on the voltage and current of each cell in the charging mode of the battery 100. The process of determining the current resistance value through the first algorithm, according to an embodiment, is described in more detail below with reference to FIG. 4.

As another example, the plurality of algorithms may include a second algorithm that determines the current resistance value of each cell based on frequency data obtained by converting current data for each cell over time into the frequency domain in the use mode in which charging and discharging of the battery 100 are repeated.

As another example, the plurality of algorithms may include a third algorithm that determines the current resistance value of each cell by performing regression analysis (e.g., Least Mean Squares, or the like) based on current value data of each cell and voltage value data of each cell in the use mode in which charging and discharging of the battery 100 are repeated.

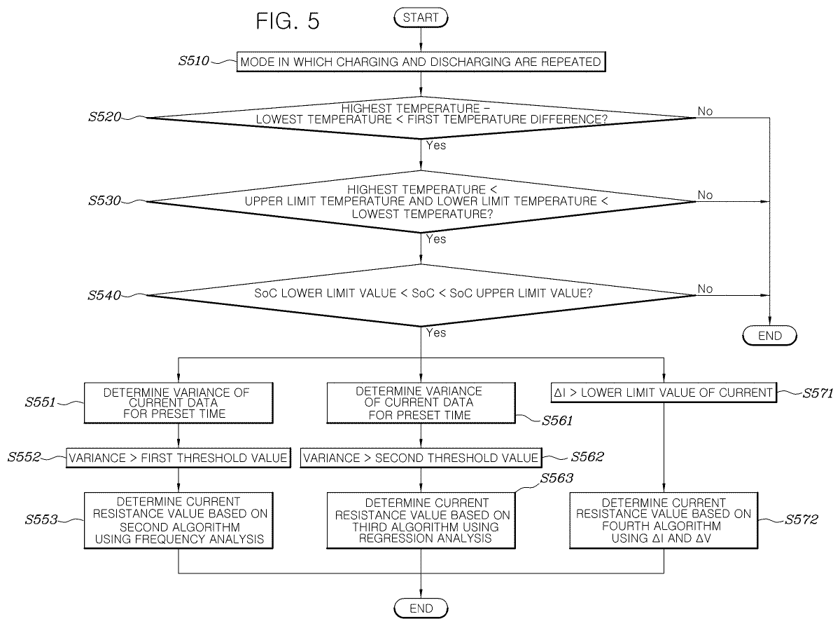

As another example, the different algorithms may include a fourth algorithm that determines the current resistance value of each cell based on a current change amount and a voltage change amount of each cell over a preset time in the use mode in which charging and discharging of the battery 100 are repeated. The process of determining the current resistance value through each of the second to fourth algorithms, according to an embodiment, is described in more detail below with reference to FIG. 5.

However, the types and number of the aforementioned algorithms are illustrative. The algorithms are not limited to the first to fourth algorithms described above, and may be set in various manners. In various embodiments, the algorithms may be set in various manners, including two or more algorithms that can independently determine the internal resistance of each cell included in the battery 100.

In an operation S340, the controller 220 may perform primary filtering based on the current resistance value and previous resistance values determined for each algorithm before the current resistance value is determined, to determine a primarily filtered resistance value.

For example, primary filtering may include an outlier removal process of comparing the current resistance value with the previous resistance values, and re-determining the current resistance value if the current resistance value is significantly different from the previous resistance values.

As another example, primary filtering may include a process of determining a primarily filtered resistance value by correcting the current resistance value based on previous resistance values and weights corresponding to the current resistance value and the previous resistance values.

In an operation S350, the controller 220 may determine a final resistance value for each of the plurality of algorithms by secondarily filtering the primarily filtered resistance value.

For example, when the number of primarily filtered resistance values corresponding to one of the plurality of algorithms is equal to or greater than a predetermined number, the controller 220 may determine the final resistance value for the algorithm based on the primarily filtered resistance values corresponding to the algorithm.

In an operation S360, the controller 220 may determine the resistance value of each cell and the SoH_{R} of the battery 100 based on the final resistance value for each of the plurality of algorithms.

In an example, the controller 220 may determine a weight based on the time when the final resistance value for each of the plurality of algorithms is determined, and may determine the value obtained by multiplying the final resistance value for each of the plurality of algorithms by each weight as the resistance value of each cell.

In an example, the controller 220 may determine the SoH_{R} based on a resistance value R_{EOL} of each cell at a preset end-of-life time, a preset initial resistance value R_{new} of each cell, and a determined resistance value Ro of each cell using the following mathematical expression 1.

[Mathematical expression 1]

$$SOHR = \frac{{R}_{EOL} - {R}_{0}}{{R}_{EOL} - {R}_{new}}$$

However, the mathematical expression for determining the SoH_{R} based on the resistance value of each cell is merely an example, and the present disclosure is not limited thereto. For example, the SoH_{R} may be determined according to various methods that may be adopted by a person having ordinary skill in the art using the resistance value of each cell.

FIG. 4 is a flowchart showing the first algorithm according to an embodiment.

Referring to FIG. 4, in an operation S410, the controller 220 may determine the current resistance value based on the first algorithm in the charging mode in which the battery 100 is charged.

In an embodiment, the controller 220 may determine the current resistance value when preset conditions are satisfied.

For example, if the value obtained by subtracting the lowest temperature from the highest temperature among obtained temperatures of the battery 100 is less than a preset first temperature difference (for example, a value set within 10 degrees Celsius), and the highest temperature is lower than a preset upper temperature and the lowest temperature is higher than a preset lower temperature, and thus preset temperature conditions are satisfied (Yes in an operation S420 and Yes in an operation S430), and if an obtained SoC of the battery 100 is greater than an SoC lower limit value and less than an SOC upper limit value, and thus preset SoC conditions are satisfied (Yes in an operation S440), the controller 220 may determine the current resistance value obtained by calculating the internal resistance of each cell of the battery 100 based on the first algorithm.

In addition, the controller 220 may determine the current resistance value based on voltage data of the battery 100 and current data of the battery 100 in the charging mode.

For example, in an operation S451, the controller 220 may store current and voltage data of each cell for a preset first time (e.g., 10 seconds) after charging starts. In an operation S452, the controller 220 may store current and voltage data of each cell for a preset second time (e.g., 10 seconds) after charging is completed. In an operation S460, the controller 220 may determine the current resistance value based on the voltage change amount and average current per cell for the preset first time after charging starts and the voltage change amount and average current per cell for the preset second time after charging ends.

FIG. 5 illustrates the second to fourth algorithms among the plurality of algorithms according to an embodiment.

Referring to FIG. 5, in an operation S510, the controller 220 may determine the current resistance value corresponding to each of the second to fourth algorithms in a mode in which charging and discharging of the battery 100 are repeated.

In an embodiment, the controller 220 may determine the current resistance value when preset conditions are satisfied.

For example, the controller 220 may determine the current resistance value for each cell of the battery 100 for each of the second to fourth algorithms that determine the SoH_{R} of the battery 100 in a mode in which charging and discharging are repeated if the value obtained by subtracting the lowest temperature from the highest temperature among temperatures of each cell is less than a preset first temperature difference (for example, a value set within 10 degrees Celsius), the highest temperature is lower than a preset upper limit temperature, and the lowest temperature is higher than a preset lower limit temperature, and thus preset temperature conditions are satisfied (Yes in an operation S520 and Yes in an operation S530), and if the obtained SoC of each cell is greater than an SoC lower limit value and less than an SoC upper limit value, and thus preset SoC conditions are satisfied (Yes in an operation S540).

In an embodiment, the process of determining the current resistance value corresponding to the second algorithm by the controller 220 based on the second algorithm may include a process in which the controller 220 collects time-series current data for a preset time (for example, 100 seconds). In an operation S551, the controller 220 may calculate the variance of the time-series current data. In an operation S553, the controller 220 may determine a final resistance value for the second algorithm based on the second algorithm using frequency analysis in a situation where the variance is greater than a preset first threshold value as determined in an operation S552.

For example, the controller 220 may include the second algorithm that performs frequency analysis based on the following mathematical expressions 2-4. In the mathematical expressions 2-4, \hat{Z}_{virtual,AC} is determined based on the second algorithm, PSD (VI) is the power spectral density of voltage-current data, PSD (II) is the power spectral density of current of current data, V_{seg.AC} is the AC component of time-series voltage data, I_{seg.AC} is the AC component of time-series current data, k is a reference time, and t is a time delay variable.

$${\hat{Z}}_{virtual , AC} = \frac{PSD ( VI )}{PSD ( II )} \qquad [ Mathematical expression 2 ]$$

$$PSD ( VI ) = {\int }_{0}^{∞} ( {V}_{seg , AC} ( k + τ ) {e}^{- jwτ} d τ * {\int }_{0}^{∞} ( {I}_{seg , AC} ( k + τ ) {e}^{jwτ} d τ \qquad [ Mathematical expression 3 ]$$

$$PSD ( II ) = {\int }_{0}^{∞} ( {I}_{seg , AC} ( k + τ ) {e}^{- jwτ} d τ * {\int }_{0}^{∞} ( {I}_{seg , AC} ( k + τ ) {e}^{jwτ} d τ \qquad [ Mathematical expression 4 ]$$

In addition, the process of determining the current resistance value corresponding to the third algorithm by the controller 220 based on the third algorithm may include a process in which the controller 220 calculates the variance of current data for a preset period of time (for example, 100 seconds) in an operation S561, and determines the current resistance value corresponding to the third algorithm based on the third algorithm using regression analysis in a situation where the variance is greater than a preset second threshold value in operations S562 and S563.

For example, the controller 220 may include the third algorithm that performs regression analysis based on the LMS logic of the following mathematical expression 5. In the mathematical expression 5, the current resistance value Rnow3 is the resistance value determined based on the third algorithm, Covariance (OCV, I) is the covariance between an open circuit voltage OCV and current I per cell, and Variance (I²) is the variance for the square value of the current.

$${R}_{now 3} = \frac{Covariance ( OCV , I )}{Variance ( {I}^{2} )} \qquad [ Mathematical expression 5 ]$$

In addition, the process of determining the current resistance value corresponding to the third algorithm by the controller 220 based on the fourth algorithm may include a process in which the controller 220 stores a current change amount ΔI and a voltage change amount ΔV in a situation where the current change amount ΔI is greater than a preset current lower limit as determined in an operation S571, and, in an operation S572, determines the current resistance value corresponding to the fourth algorithm based on stored current change amounts ΔI and voltage change amounts ΔV when a preset number (for example, 100) of current change amounts ΔI and voltage change amounts ΔV are stored.

For example, the controller 220 may include the fourth algorithm that determines the current resistance value based on mathematical expression 6 below. In the mathematical expression 6, the current resistance value Rnow4 is the resistance value of each cell determined based on the fourth algorithm, N is a preset number for determining the current resistance value based on the fourth algorithm, the current change amount ΔI is a current change amount in each cell of the battery 100 in an i-th situation in which the current change amount ΔI is greater than the preset current lower limit, and the voltage change amount ΔV is a voltage change amount in each cell of the battery 100 in the i-th situation in which the current change amount ΔI is greater than the preset current lower limit.

$${R}_{now 4} = \frac{1}{N} {\sum }_{1}^{N} \frac{Δ {V}_{i}}{Δ {I}_{i}} \qquad [ Mathematical expression 6 ]$$

The types and number of algorithms for determining the current resistance value in the charging mode or the mode in which charging and discharging are repeated in FIGS. 4 and 5 are illustrative, and different types of algorithms from the first to fourth algorithms described above may be set or a different number, i.e., two or more, of algorithms may be set.

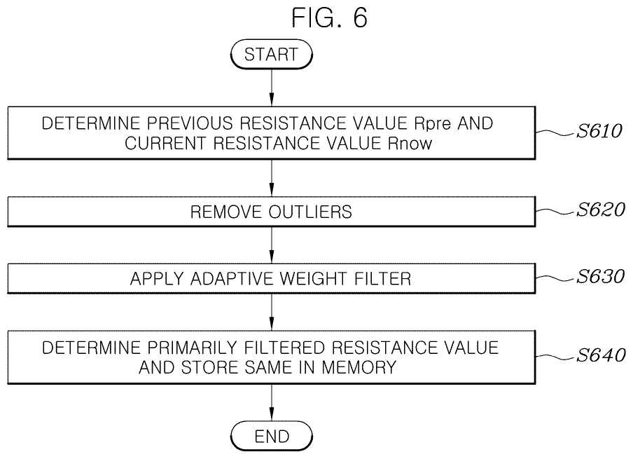

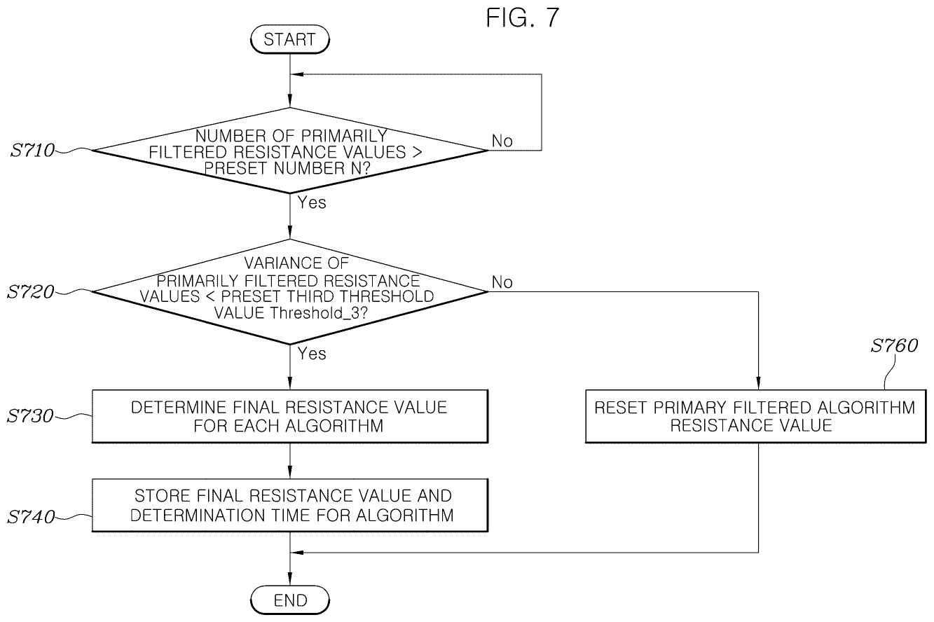

Hereinafter, based on the first algorithm, a process in which the controller 220 determines the current resistance value based on the first algorithm and performs primary filtering based on previous resistance values and the current resistance value to determine the primarily filtered resistance value, and a process in which the controller 220 determines the final resistance value corresponding to the first algorithm based on the primarily filtered resistance value corresponding to the first algorithm, according to an embodiment, are described in more detail with reference to FIGS. 6 and 7.

FIG. 6 is a flowchart illustrating the primary filtering process according to an embodiment.

Referring to FIG. 6, in an operation S610, the controller 220 may determine a previous resistance value Rpre and the current resistance value Rnow in order to perform primary filtering. For example, the controller 220 may determine the current resistance value Rnow based on the first algorithm, and may determine, as the previous resistance value Rpre, the primarily filtered resistance value determined based on the first algorithm before determining the current resistance value Rnow.

In an operation S620, the controller 220 may perform primary filtering to remove outliers. For example, if the current resistance value Rnow is greater than the value obtained by multiplying the previous resistance value Rpre by a preset upper multiple (e.g., 200%), or if the current resistance value Rnow is less than the value obtained by multiplying the previous resistance value Rpre by a preset lower multiple (e.g., 50%), the controller 220 may re-determine the current resistance value Rnow based on the first algorithm without storing the determined current resistance value Rnow.

In an operation S630, the controller 220 may perform primary filtering including an adaptive weight filter to determine a primarily filtered resistance value. In an operation S640, the controller 220 may store the determined primarily filtered resistance value in the memory 230. For example, the controller 220 may determine the primarily filtered resistance value based on a product of the current resistance value Rnow and a first weight corresponding to the current resistance value Rnow and a product of the previous resistance value Rpre and a second weight corresponding to the previous resistance value Rpre. According to an embodiment, the controller 220 may determine the primary first filtering resistance value based on the following mathematical expression 7 in which the first weight (a) greater than or equal to 100 is applied if the current resistance value Rnow is greater than the previous resistance value Rpre, and may determine the primarily filtered resistance value based on the following mathematical expression 8 in which the second weight (b) less than 100 is applied when the current resistance value Rnow is less than the previous resistance value Rpre.

$$Rnow * \frac{100}{a} + Rpre * ( 1 - \frac{100}{a} ) , a \geq 100 \qquad [ Mathematical expression 7 ]$$

$$Rnow * \frac{b}{100} + Rpre * ( 1 - \frac{b}{100} ) , b < 100 \qquad [ Mathematical expression 8 ]$$

In an embodiment, the controller 220 may sequentially accumulate and store primarily filtered resistance values determined as shown in Table 1 below for the algorithms used, and may repeat the process until the accumulated data reaches a preset number N. In Table 1, N is the number of primarily filtered resistance values preset as a condition for determining the final resistance value for each algorithm, Ralgorithm_1 is the final resistance value of the first algorithm corresponding to Algorithm 1, Ralgorithm_2 is the final resistance value of the second algorithm corresponding to Algorithm 2, Ralgorithm_3 is the final resistance value of the third algorithm corresponding to Algorithm 3, Ralgorithm_4 is the final resistance value of the fourth algorithm corresponding to Algorithm 4, and R final is the final resistance values for the plurality of algorithms.

TABLE 1

| | | | | | Final | |
|---|---|---|---|---|---|---|
| | | | | | resistance | |
| | | | | | value for | |
| | Primarily filtered | | | | each | |
| | resistance value(mV) | | | | algorithm | Determination |
| | 1 | 2 | . . . | N | (R_final) | time |
| Ralgorithm_1 | 0.70 | 0.69 | . . . | — | 0.70(mV) | 2024 Jan. 1 |
| Ralgorithm_2 | 0.68 | | . . . | — | 0.69(mV) | 2024 Feb. 1 |
| Ralgorithm_3 | 0.70 | | . . . | — | 0.71(mV) | 2024 Feb. 1 |
| Ralgorithm_4 | 0.70 | 0.71 | . . . | — | 0.70(mV) | 2024 Feb. 1 |

In an embodiment, if the number of primarily filtered resistance values determined based on the first algorithm reaches Z, the controller 220 may perform secondary filtering. Hereinafter, the process of performing secondary filtering when the number of primarily filtered resistance values reaches N, according to an embodiment, is described in more detail with reference to FIG. 7.

FIG. 7 is a flowchart illustrating the secondary filtering process according to an embodiment.

Referring to FIG. 7, the controller 220 may perform secondary filtering when preset conditions are satisfied.

For example, in an operation S710, the controller 220 may determine whether the number of primarily filtered resistance values corresponds to the preset number N that is a condition for performing secondary filtering. In an operation S720, the controller 220 may determine whether the variance of the primarily filtered resistance values is greater than a preset lower limit, a third threshold value Threshold 3.

If the variance of the primarily filtered resistance values is determined to be less than or equal to the third threshold value Threshold 3, which is the preset lower limit (No in the operation S720), the controller 220 may reset the primarily filtered resistance values corresponding to the algorithm in an operation S750.

If the number of primarily filtered resistance values corresponds to the preset number N for performing secondary filtering (Yes in the operation S710) and the variance of the primarily filtered resistance values is determined to be greater than the third threshold value Threshold 3, which is the preset lower limit (Yes in the operation S720), the controller 220 may determine the final resistance value for each algorithm in an operation S730. In an operation S740, the controller 220 may store the final resistance value determined in the operation S730 for each algorithm and may store the determination time when the final resistance value for each algorithm is determined in the operation S730.

For example, the final resistance value for each algorithm determined by performing secondary filtering and the determination time may be stored as shown in Table 2 below. In Table 2, N is the number of primarily filtered resistance values set as a condition for determining the final resistance value for each algorithm, Ralgorithm_1 is the final resistance value of the first algorithm corresponding to Algorithm 1, Ralgorithm_2 is the final resistance value of the second algorithm corresponding to Algorithm 2, Ralgorithm_3 is the final resistance value of the third algorithm corresponding to Algorithm 3, Ralgorithm_4 is the final resistance value of the fourth algorithm corresponding to Algorithm 4, and R final is the final resistance values for the algorithms.

TABLE 2

| | | | | | Final | |
|---|---|---|---|---|---|---|
| | | | | | resistance | |
| | | | | | value for | |
| | Primarily filtered | | | | each | |
| | resistance value(mV) | | | | algorithm | Determination |
| | 1 | 2 | . . . | N | (R_final) | time |
| Ralgorithm_1 | 0.70 | 0.69 | . . . | 0.70 | 0.71 mV | 2024 Feb. 2 |
| Ralgorithm_2 | 0.68 | 0.69 | . . . | — | 0.69 mV | 2024 Feb. 1 |
| Ralgorithm_3 | 0.70 | 0.72 | . . . | — | 0.71 mV | 2024 Feb. 1 |
| Ralgorithm_4 | 0.70 | 0.71 | . . . | — | 0.70 mV | 2024 Feb. 1 |

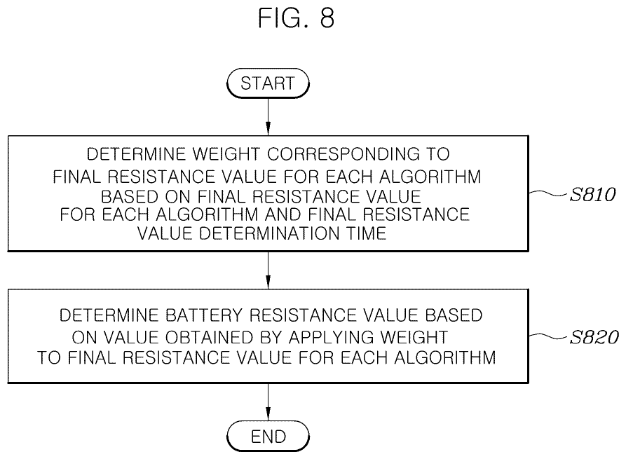

FIG. 8 is a flowchart illustrating a process of determining a resistance value of each cell according to an embodiment.

In an operation S810, the controller 220 may determine a weight corresponding to each of the final resistance values for the plurality of algorithms based on the final resistance values and determination points in time when the final resistance values are determined.

According to the embodiment, the controller 220 may determine the weight corresponding to each of the final resistance values such that the weight increases as the difference between the determination time of the final resistance value of each algorithm and the determination time of the final resistance value decreases. In an embodiment, weights may be set such that the sum of all weights corresponding to the final resistance values is at least approximately equal to 1.

For example, based on the situation shown in [Table 1], it may be assumed that the time when the final resistance value is determined is 2024.02.02, the time when a first weight, which is the weight for the first algorithm final resistance value Ralgorithm_1 corresponding to Algorithm 1, is determined is 2024.01.01, and the time when a second weight b, which is the weight for the second algorithm final resistance value Ralgorithm_2 corresponding to Algorithm 2, is determined, the time when a third weight c, which is the weight for the third algorithm final resistance value Ralgorithm_3 corresponding to Algorithm 3, is determined, and the time when a fourth weight d, which is the weight for the fourth algorithm final resistance value Ralgorithm_4 corresponding to Algorithm 4, is determined are all 2024.02.01. Thus, in this example, the controller 220 determines the first weight a, which has the largest difference from the final resistance value determination time as the smallest value, 0.1, and determines the second to fourth weights b, c and d, which have similar differences from the final resistance value determination time, as 0.3.

As another example, based on the situation shown in [Table 2], it may be assumed that the time when the final resistance value is determined is 2024.02.02, the time when the first weight, which is the weight for the first algorithm final resistance value Ralgorithm_1 corresponding to Algorithm 1, is determined is 2024.02.02, and the time when a second weight b, which is the weight for the second algorithm final resistance value Ralgorithm_2 corresponding to Algorithm 2, is determined, the time when a third weight c, which is the weight for the third algorithm final resistance value Ralgorithm_3 corresponding to Algorithm 3, is determined, and the time when the fourth weight d, which is the weight for the fourth algorithm final resistance value Ralgorithm_4 corresponding to Algorithm 4, is determined are all 2024.02.01. Thus, in this example, the controller 220 determines the first weight a having the smallest difference from the final resistance value determination time as the largest value, 0.4, and determines the second to fourth weights b, c, and d having similar differences from the final resistance value determination time as 0.2.

The specific values of the above-described determination times and weights are examples, and the determination time and weight data are not limited to the above-described values.

In an operation S820, The controller 220 may determine the resistance value of each cell based on the values obtained by applying the weights to the final resistance values for the plurality of algorithms.

For example, the controller 220 may determine the resistance value of each cell based on the following mathematical expression 9. In the mathematical expression 9, Rtotal_final is the resistance value of each cell, a is the first weight which is the weight for the first algorithm final resistance value Ralgorithm_1 corresponding to Algorithm 1, b is the second weight which is the weight for the second algorithm final resistance value Ralgorithm_2 corresponding to Algorithm_2, c is the third weight which is the weight for the third algorithm final resistance value Ralgorithm_3 corresponding to Algorithm 3, and d is the fourth weight which is the weight for the fourth algorithm final resistance value Ralgorithm_4 corresponding to Algorithm 4.

Rₜₒₜₐₗ_{_{final}}=a*R_{algorithm}_{₁}+b*R_{algorithm}_{₂}+C*R_{algorithm}_{₃}+d*R_{algorithm}_{₄} [Mathematical expression 9]

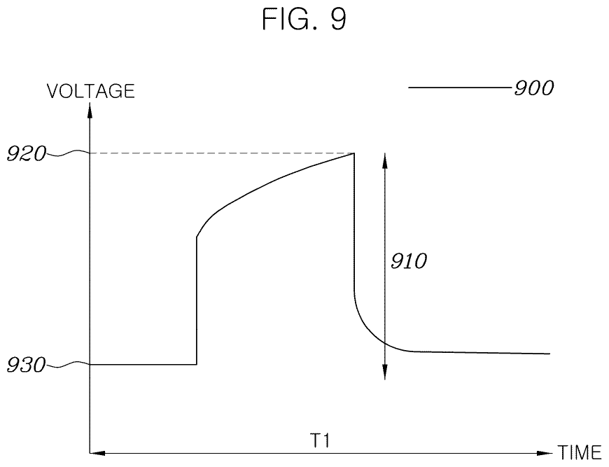

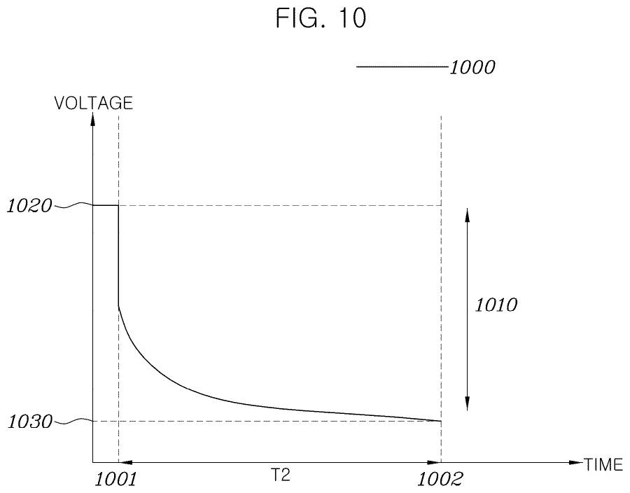

FIGS. 9 and 10 illustrate the first algorithm in the charging mode according to the embodiment.

Referring to FIG. 9, a first voltage graph 900 shows a voltage change amount in a cell included in the battery 100 during a preset first time T1 after charging of the battery 100 has started. Referring to FIG. 10, a second voltage graph 1000 shows a voltage change amount in a cell included in the battery 100 during a preset second time T2 after charging of the battery 100 has ended.

The first algorithm may be an algorithm that determines the first algorithm final resistance value Ralgorithm_1 based on a first voltage change amount 910, which is the voltage change amount during the preset first time T1 close to the time at which charging starts, a first average current amount, which is the average current during the first time T1, a second voltage change amount 1010, which is a voltage change amount during the preset second time T2 close to the time at which charging ends, and a second average current amount, which is the average current during the second time T2. For example, the first algorithm may be an algorithm that determines the first algorithm final resistance value Ralgorithm_1 based on the following mathematical expressions 10-12. In the mathematical expressions 10-12, Ralgorithm_1 is the first algorithm final resistance value, Rinitial is a resistance value determined based on the first voltage change amount 910 and the first average current during the first time T1, and Rend is a resistance value determined based on the second voltage change amount 1010 and the second average current during the second time T2.

$${R}_{{algorithm}_{1}} = \frac{{R}_{initial} + {R}_{end}}{2} \qquad [ Mathematical Expression 10 ]$$

$${R}_{initial} = \frac{first voltage change amount}{\begin{matrix}average current amount \\ during first time ( T1 )\end{matrix}} \qquad [ Mathematical Expression 11 ]$$

$${R}_{end} = \frac{second voltage change amount}{\begin{matrix}average current amount \\ during second time ( T2 )\end{matrix}} \qquad [ Mathematical Expression 12 ]$$

In an embodiment, the first voltage change amount 910 may be a value obtained by subtracting the minimum voltage value 930 during the first time T1 after charging starts from the maximum voltage value 920 during the first time T1 after charging starts, and the second voltage change amount 1010 may be a value obtained by subtracting the minimum voltage value 1030 during the second time T2 after charging starts from the maximum voltage value 1020 during the second time T2 after charging starts.

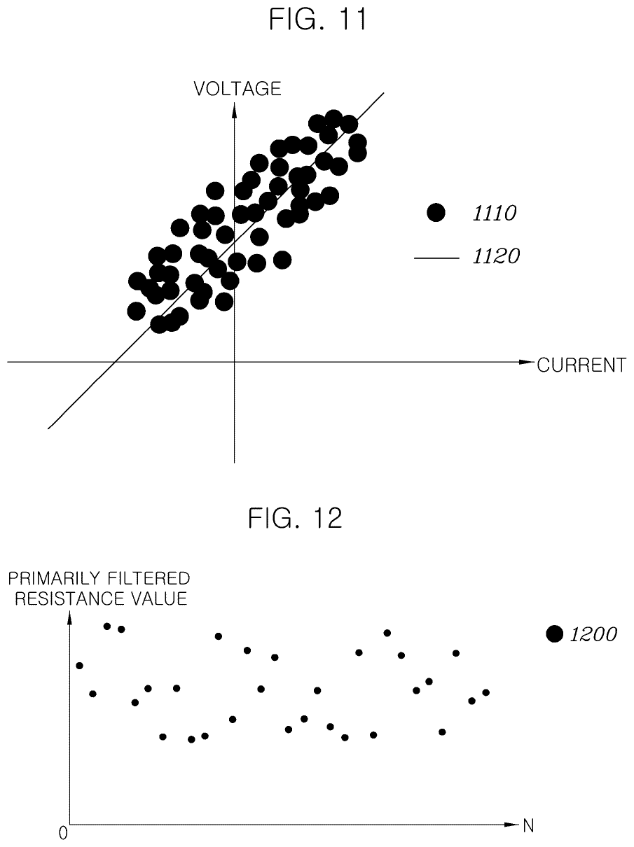

FIG. 11 illustrates the third algorithm in the mode in which charging and discharging are repeated according to the embodiment.

FIG. 11 shows a first voltage-current graph 1110 representing current values and voltage values of cells at each preset time in the mode in which charging and discharging of the battery 100 are repeated, and a second voltage-current graph 1120 determined based on regression analysis.

The third algorithm may be an algorithm that performs regression analysis (e.g., Least Mean Squares or the like) based on first current-voltage data obtained by repeatedly collecting current and voltage values of each cell of the battery 100 for a preset third time to calculates the final resistance value Ralgorithm_3. The regression analysis may be performed based on a first-order function graph in the form of y=ax+b.

The first voltage-current graph 1110 is a scatter graph that depicts a plurality of pieces of first current-voltage data, and the second voltage-current graph 1120 is a first-order function graph in the form of y=ax+b derived through regression analysis.

FIGS. 12 13 illustrate the secondary filtering process according to the embodiment.

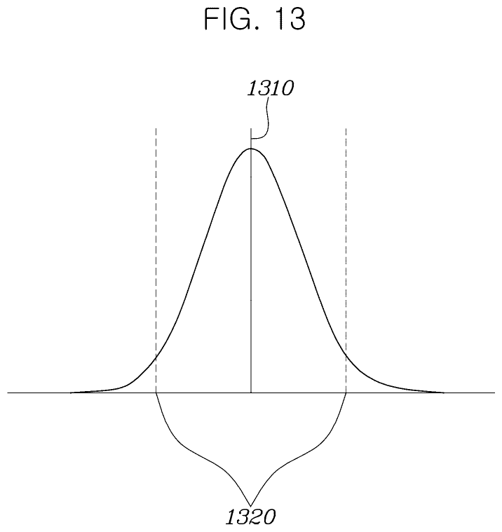

Referring to FIG. 12, a filtering resistance value graph 1200 shows a preset number N of primarily filtered resistance values when secondary filtering is performed when the number of primarily filtered resistance values corresponding to the first algorithm reaches the preset number N. Referring to FIG. 13, a graph 1300 shows a preset value 1310 (e.g., twice the standard deviation of the primarily filtered resistance values) as a limit value of the variance, an average value 1320 of the primarily filtered resistance values corresponding to the first algorithm, and a normal distribution of the primarily filtered resistance values.

If the variance of the primarily filtered resistance values is less than a preset third threshold value Threshold 3, the first algorithm final resistance value Ralgorithm_1 may be determined based on the preset number N of primarily filtered resistance values.

If the variance of the preset number N of primarily filtered resistance values is greater than the preset third threshold value Threshold 3, the preset number N of primarily filtered resistance values are initialized, and primarily filtered resistance values may be calculated again based on the first algorithm until the number of primarily filtered resistance values reach the preset number N.

However, the aforementioned initialization does not necessarily have to be performed on all of primarily filtered resistance values. For example, the initialization may be selectively performed only on primarily filtered resistance values with a large variance.

For example, referring to FIG. 13, if there are values having a variance greater than the preset value 1310 among the primarily filtered resistance values, only the primarily filtered resistance values having a variance greater than the preset value 1310 are initialized, and the first algorithm final resistance value Ralgorithm_1 may be determined based on the values excluding the initialized primarily filtered resistance values. In an embodiment, the first algorithm final resistance value Ralgorithm_1 may be set to correspond to the average value 1320 of the primarily filtered resistance values that satisfy the preset conditions.

Embodiments of the present disclosure provide a battery diagnostic device and method capable of determining the SoH_{R} of a battery, and a vehicle including the device.

Embodiments of the present disclosure provide a battery diagnostic device and method capable of determining the SoH_{R} of a battery under various conditions based on a plurality of different algorithms, and a vehicle including the device.

Embodiments of the present disclosure provide a battery diagnostic device and method capable of determining the SoH_{R} of a battery regardless of the type of battery or vehicle, and a vehicle including the device.

Embodiments of the present disclosure provide a battery diagnostic device and method capable of improving the accuracy of a determined SoH_{R} of a battery, and a vehicle including the device.

The effects to be achieved in the present disclosure are not limited to the effects mentioned above. Other effects not mentioned herein should be more clearly understood by a person having ordinary skill in the art to which the present disclosure pertains from the description below.

Although example embodiments of the present disclosure have been described for illustrative purposes, those having ordinary skill in the art should appreciate that various modifications, additions, and substitutions are possible, without departing from the scope and spirit of the disclosure as claimed in the accompanying claims.

What is claimed is:

1. A battery diagnosing device comprising:
a controller configured to
determine, for each cell of a battery, final resistance values based on a plurality of algorithms,
determine a resistance value of each cell of the battery based on i) the final resistance values determined based on the plurality of algorithms and ii) respective determination times at which the final resistance values are determined, and
determine a state of health based on resistance (SoH_{R}) of the battery based on the resistance value of each cell; and
an output device configured to transmit the SoH_{R} to an external device.

2. The battery diagnosing device of claim 1, wherein the controller is configured to:
determine weights corresponding to the final resistance values for each of the plurality of algorithms based on the respective determination times; and
determine the resistance value of each cell based on values obtained by applying the weights to the corresponding final resistance values.

3. The battery diagnosing device of claim 2, wherein the controller is configured to set the weights such that a sum of the weights is at least approximately equal to 1.

4. The battery diagnosing device of claim 2, wherein the controller is configured to determine the weights based on differences between the respective determination times at which the final resistance values are determined and a determination time when the resistance value of each cell is determined.

5. The battery diagnosing device of claim 4, wherein the controller is configured to determine the weights such that the weights increase as a difference between the determination time of the resistance value and the determination time of the final resistance values to which the weights correspond decreases.

6. The battery diagnosing device of claim 1, wherein the controller is configured to:
determine a current resistance value for each of the plurality of algorithms based on each of the plurality of algorithms; and
determine a primarily filtered resistance value based on the current resistance value and a previous resistance value determined for each of the plurality of algorithms prior to the current resistance value.

7. The battery diagnosing device of claim 6, wherein the controller s configured to re-determine the current resistance value based on a determination that the current resistance value is greater than a value obtained by multiplying the previous resistance value by a preset upper limit multiple, or that the current resistance value is less than a value obtained by multiplying the previous resistance value by a preset lower limit multiple.

8. The battery diagnosing device of claim 6, wherein the controller is configured to determine the primarily filtered resistance value as a sum of a value obtained by multiplying the current resistance value by a weight corresponding to the current resistance value and a value obtained by multiplying the previous resistance value by a weight corresponding to the previous resistance value.

9. The battery diagnosing device of claim 6, wherein the controller configured to:
store the primarily filtered resistance value;
determine the primarily filtered resistance value as the previous resistance value; and
re-determine the current resistance value.

10. The battery diagnosing device of claim 6, wherein, based on a determination that a preset number of primarily filtered resistance values for a particular algorithm among the plurality of algorithms have been stored, the controller is configured to determine a final resistance value for the particular algorithm based on the primarily filtered resistance values.

11. The battery diagnosing device of claim 10, wherein the controller is further configured to determine a final resistance value for a particular algorithm among the plurality of algorithms by further considering whether a variance of the primarily filtered resistance values for the particular algorithm is equal to or less than a preset value.

12. The battery diagnosing device of claim 1, wherein the controller is configured to:
determine whether preset execution conditions are satisfied for each of the plurality of algorithms; and
determine the final resistance values for one or more algorithms, among the plurality of algorithms, that satisfy the preset execution conditions.

13. The battery diagnosing device of claim 12, wherein the preset execution conditions include whether a temperature of each cell of the battery satisfies preset temperature conditions.

14. The battery diagnosing device of claim 12, wherein the preset execution conditions include whether a state of charge (SoC) of each cell of the battery satisfies preset SoC conditions.

15. The battery diagnosing device of claim 1, wherein the plurality of algorithms includes an algorithm for determining a final resistance value based on a voltage change amount for a preset first time after charging starts, an average current for the preset first time, a voltage change amount for a preset second time after charging ends, and an average current for the preset second time in a charging mode of the battery.

16. The battery diagnosing device of claim 1, wherein the plurality of algorithms includes an algorithm for determining a final resistance value based on frequency data obtained by converting current data including a current value of each cell over a preset time into a frequency domain in a mode in which charging and discharging of the battery are repeated.

17. The battery diagnosing device of claim 1, wherein the plurality of for algorithms includes an algorithm determining a final resistance value by performing least mean squares based on a current value and a voltage value of each cell for a preset time period in a mode in which charging and discharging of the battery are repeated.

18. The battery diagnosing device of claim 1, wherein the plurality of algorithms includes an algorithm for determining a final resistance value based on average values of a current change amount in each cell during a preset time and a voltage change amount in each cell during the preset time in a mode in which charging and discharging of the battery are repeated.

19. A method of diagnosing a battery comprising:
determining, by a controller, final resistance values based on a plurality of algorithms;
determining, by the controller, a resistance value of each cell of the battery based on i) the final resistance values determined based on the plurality of algorithms and ii) respective determination times at which the final resistance values are determined;
determining, by the controller, a state of health based on resistance (SoH_{R}) of the battery based on the resistance value of each cell; and
transmitting the SoH_{R} to an external device.

20. A vehicle comprising:
a battery including a plurality of cells; and
a battery diagnostic device configured to
determine final resistance values based on a plurality of algorithms,
determine a resistance value of each cell of the plurality of cells based on i) the final resistance values determined based on the plurality of algorithms and ii) respective determination times at which the final resistance values are determined, and
determine a state of health based on resistance (SoH_{R}) of the battery based on the resistance value of each cell.
